(19) United States
(12) Patent Application Publication
(10) Pub. No.: US 2010/0327251 A1
(43) Pub. Date: Dec. 30, 2010

(54) PHASE CHANGE MEMORY DEVICE HAVING PARTIALLY CONFINED HEATING ELECTRODES CAPABLE OF REDUCING HEATING DISTURBANCES BETWEEN ADJACENT MEMORY CELLS

(75) Inventor: Hae Chan PARK, Gyeonggi-do (KR)

Correspondence Address: LADAS & PARRY LLP, 224 SOUTH MICHIGAN AVENUE, SUITE 1600, CHICAGO, IL, 60604, US

(73) Assignee: HYNIX SEMICONDUCTOR INC., Gyeonggi-do (KR)

(21) Appl. No.: 12/647,595

(22) Filed: Dec. 28, 2009

(30) Foreign Application Priority Data
Jun. 30, 2009 (KR) 10-2009-0058916
Sep. 30, 2009 (KR) 10-2009-0093614

(51) Int. Cl. H01L 47/00; H01L 21/06

(52) U.S. Cl. 257/2; 438/102; 257/E47.001; 257/E21.068

(57) ABSTRACT

A phase change memory device having partially confined heating electrodes capable of reducing thermal disturbances between adjacent memory cells is presented. The phase change memory device includes a plurality of active regions, a plurality of switching elements, a plurality of heating electrodes, and a plurality of phase change structure lines. The active regions being linear and parallel to each other. The switching elements are coupled to the active regions. The heating electrodes are on and coupled to the switching elements. The phase change structure lines are coupled to the heating electrodes such that the phase change structure lines are substantially vertical to the active regions. The phase change structure lines includes a plurality of plugs projecting downwards that couple to overlapped portions of the heating electrodes.

### CROSS-REFERENCES TO RELATED PATENT APPLICATION

The present application claims priority under 35 U.S.C 119(a) to Korean Application Nos. 10-2009-0058916 and 10-2009-0093614, filed on Jun. 30, 2009 and Sep. 30, 2009, in the Korean Intellectual Property Office, which are incorporated herein by reference in its entirety as set forth in full.

### BACKGROUND

1. Technical Field

The embodiment relates to a nonvolatile memory and, more particularly, to a phase change memory device capable of reducing disturbance and a method of manufacturing the same.

2. Related Art

Semiconductor memory devices can be classified into volatile memory devices and nonvolatile memory devices depending on whether or not storage data is retained when supply of power is stopped. The volatile memory device includes a dynamic random access memory (DRAM) device and a static random access memory (SRAM) device and the nonvolatile memory device includes a flash memory and an electrically erasable programmable read only memory (EEPROM) device.

The flash memory device which is the nonvolatile memory device is primarily used for digital cameras, mobile phones, or MP3 players which are an electronic apparatus commonly used in recent years.

However, since the flash memory device takes a long time to record and read data, further research and a development of a new semiconductor device such as a magnetic random access memory (MRAM), a ferroelectric random access memory (FRAM), or a phase-change memory random access memory (PCRAM) are in progress in order to substitute the flash memory device.

As the substitution device, the phase-change memory device uses as a storage medium a phase-change material causing mutual phase-change into a crystal state and an amorphous state by using heat. As the phase-change material, a chalcogenide compound composed of germanium (GE), antimony (Sb), and tellurium (Te), that is, a GST material is primarily used.

A heat source of the phase-change material is current and the amount of heat is dependent upon the intensity and supply time of current. At this time, since the phase change material has resistances of different magnitudes depending on a crystal state, logic information is determined depending on the difference in resistance.

However, as the integration density of the phase change memory device also decreases, a gap between heating electrodes also decreases. As a result, in the case where heat is applied to a predetermined cell from which information is acquired by providing current in order to perform a reading operation, an adjacent cell that previously performed the writing operation is subjected to thermal disturbance. Such thermal disturbances can cause errors in output information processing operations of phase change memory devices.

### SUMMARY

The phase change memory device can include: a semiconductor substrate; a plurality of active regions having a line shape which are configured to be formed on the semiconductor substrate and disposed in parallel to each other at predetermined intervals; a plurality of phase change structure lines configured to be formed on the top of the semiconductor substrate and disposed parallel to each other at predetermined intervals while being vertical to the active regions; and a heating electrode configured to be positioned at an intersection portion of the active region and the phase change structure line and electrically connect the phase change structure line, wherein the plurality of phase change structure lines are spaced from the heating electrode by a predetermined distance and a curve for contacting the heating electrode is formed at each overlapped portion of the heating electrode on the bottom of the phase change structure line.

The phase change memory device can include: a plurality of active regions having a line shape configured to be disposed parallel to each other at predetermined intervals; a plurality of switching elements configured to be formed at a predetermined portion of the active region; a plurality of heating electrodes configured to be formed on the switching elements, respectively; and a plurality of phase change structure lines configured to electrically connect the heating electrodes and arranged vertical to the active regions, respectively, wherein the phase change structure line includes a plurality of plugs projecting downwards to contact the heating electrodes at portions overlapped with the heating electrodes on the bottoms thereof.

The method of manufacturing the phase change memory device can includes: forming a plurality of active regions having a line shape formed on a semiconductor substrate and disposed in parallel to each other at predetermined intervals; forming a first interlayer insulating layer including a plurality of switching elements electrically connected with the active region on the top of the semiconductor substrate where the active region is formed; forming a second interlayer insulating layer having a vertical trench for exposing the switching elements arranged in two columns on the first interlayer insulating layer; forming a preliminary heating electrode pattern on a side wall of the vertical trench; forming heating electrodes on the switching elements by separating the preliminary heating electrode pattern; burying a third interlayer insulating layer in gaps between the heating electrodes; forming a fourth interlayer insulating layer including a micro-trench which extends parallel to the active region and exposes the heating electrode on the second and third interlayer insulating layers; and forming a phase change structure line to extend in a direction vertical to the active region while contacting the heating electrode exposed by the micro-trench.

These and other features, aspects, and embodiments are described below in the section “Detailed Description.”

### BRIEF DESCRIPTION OF THE DRAWINGS

Features, aspects, and embodiments are described in conjunction with the attached drawings, in which:

FIGS. 1 to 5 are plan views of an exemplary phase change memory device according to one embodiment;

FIGS. 6 to 10 are cross-sectional views taken along lines x-x′ and y-y′ of each of FIGS. 1 to 5 according to one embodiment;

FIG. 11 is a plan view of an exemplary phase change memory device according to a comparative example;

FIG. 12 is a cross-sectional view taken along lines x-x′ and y-y′ of FIG. 11;

FIG. 13 is a diagram comparing heat transmission paths of one embodiment with a comparative example with each other; and

FIG. 14 is a cross-sectional view of an exemplary phase-changeable memory device according to another embodiment.

### DETAILED DESCRIPTION

Hereinafter, a preferred embodiment of the present invention will be described with reference to the accompanying drawings.

Advantages and characteristics of the present invention, and a method for achieving them will be apparent with reference to embodiments described below in addition to the accompanying drawings. However, the present invention is not limited to the exemplary embodiments to be described below but may be implemented in various forms. Therefore, the exemplary embodiments are provided to enable those skilled in the art to thoroughly understand the teaching of the present invention and to completely information the scope of the present invention and the exemplary embodiment is just defined by the scope of the appended claims. Throughout the specification, like elements refer to like reference numerals.

In the embodiment, a scheme in which a heating electrode is formed by a partially-confined trench method which is one of methods for reducing reset current of a phase change memory device will be described.

Further, in the embodiment, a phase change memory device capable of extending a heat transmission path in an extension direction of a phase change structure line that has a problem in thermal disturbance will be described.

Hereinafter, the phase change memory device will be described in more detail.

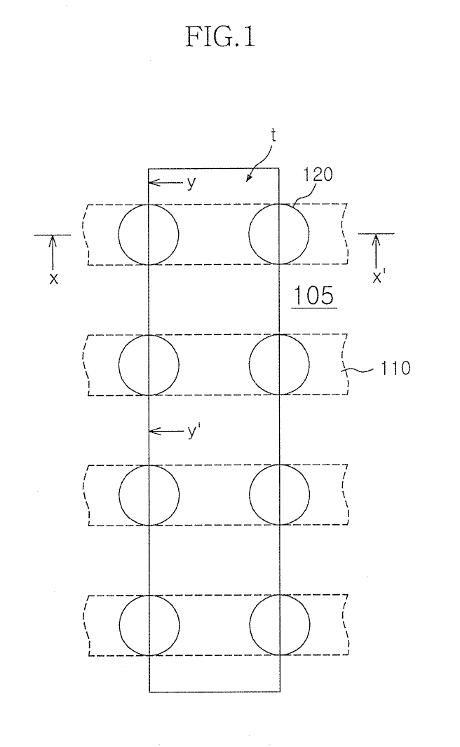

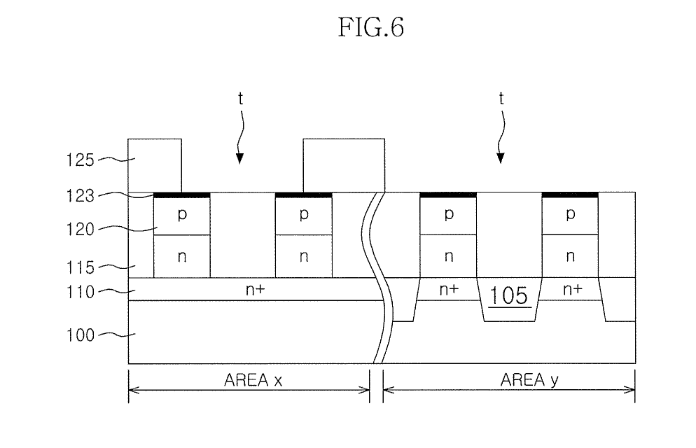

FIGS. 1 to 5 are plan views of an exemplary phase change memory device according to one embodiment and FIGS. 6 to 10 are cross-sectional views taken along lines x-x′ and y-y′ of each of FIGS. 1 to 5 according to one embodiment. In FIGS. 6 to 10, an area x represents an area taken along line x-x′ and an area y represents an area taken along line y-y′.

First, referring to FIGS. 1 and 6, a semiconductor substrate 100 including a plurality of switching elements 120 is provided.

Herein, the semiconductor substrate 100 can be, for example, a silicon wafer containing impurities and a memory cell area and a peripheral circuit area can be separated from each other. A plurality of active regions 110 can be defined in the memory cell area of the semiconductor substrate 100. The active region 110, for example, can have a line shape and can serve as a word line of the phase change memory device. Further, the active region 110 can be defined by forming an isolation region 105 at a predetermined portion of the semiconductor substrate 100 and the active region 110 can be an n-type impurity region.

A first interlayer insulating layer 115 is formed on the top of the semiconductor substrate 100 where the active region 110 is defined and the switching element 120 is formed that electrically couples to the active region 110 in the first interlayer insulating layer 115. One switching element 120 can be formed in each memory cell and can be an SEG diode 120 formed by growing the active region 110 using a selective epitaxial growth (SEG) scheme. The switching element 120 can be formed by the following method. After the first interlayer insulating layer 115 is deposited on the top of the semiconductor substrate 100 where the active region 110 is defined, a contact hole (not shown) is formed that exposes a predetermined portion of the active region 110. Subsequently, after an n-type SEG layer is formed by growing the exposed active region 110, the diode 120 can be formed by injecting p-type impurities into the n-type SEG layer.

Meanwhile, as integration density of the phase change memory device increases, lower wire resistances are required. For this, the phase change memory device can be configured to include a metal word line 1120 formed on the top of the semiconductor substrate 100 to electrically coupled to the active region 110 through a electrical conduit 1115 filling in a hole 1110 as shown in FIG. 14. At this time, the metal word line 1120 can be formed to overlap with the active region 110 and can complement the high resistance of the active region 110. However, since single crystal growth cannot be made on the metal word line 1120, then the a SEG diode cannot be used as the switching element 120. Therefore, when the metal word line 1120 is applied to the phase change memory device, a polysilicon diode 120a can be used as the switching element 120 as a metal schottky diode. As a result, in the embodiment, the switching element 120 will include both the SEG diode and the metal schottky diode. The plurality of switching elements 120 can be formed in a matrix so as to be spaced from each other at regular intervals in row and column directions.

A second interlayer insulating layer 125 including a trench t can be formed on the top of the first interlayer insulating layer 115 including the switching element 120. The trench t is an opening for exposing the plurality of switching elements 120. In the embodiment, one trench t can expose the plurality of switching elements 120 that are arranged in two adjacent columns. The trench t is vertical to a long axis of the active region 110 and in the embodiment, the trench t is referred to as a vertical trench.

For example, the vertical trench t of the embodiment can partially expose eight switching elements 120 that are arranged in two adjacent columns. Preferably, the vertical trench t can be positioned so that a long-axis edge of the vertical trench t passes through the center of the switching elements 120.

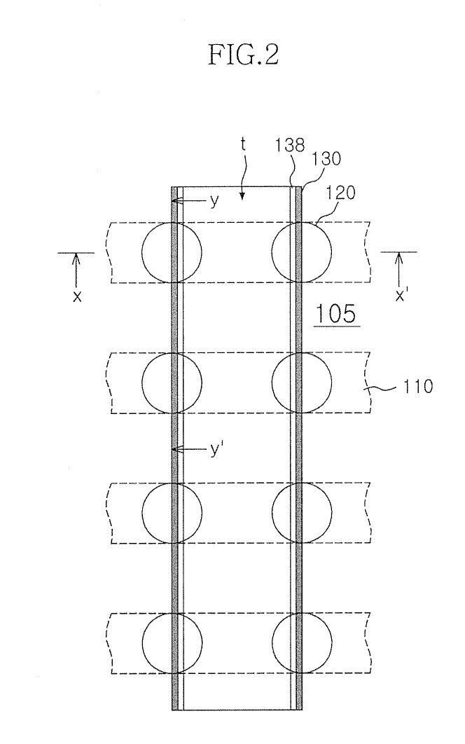

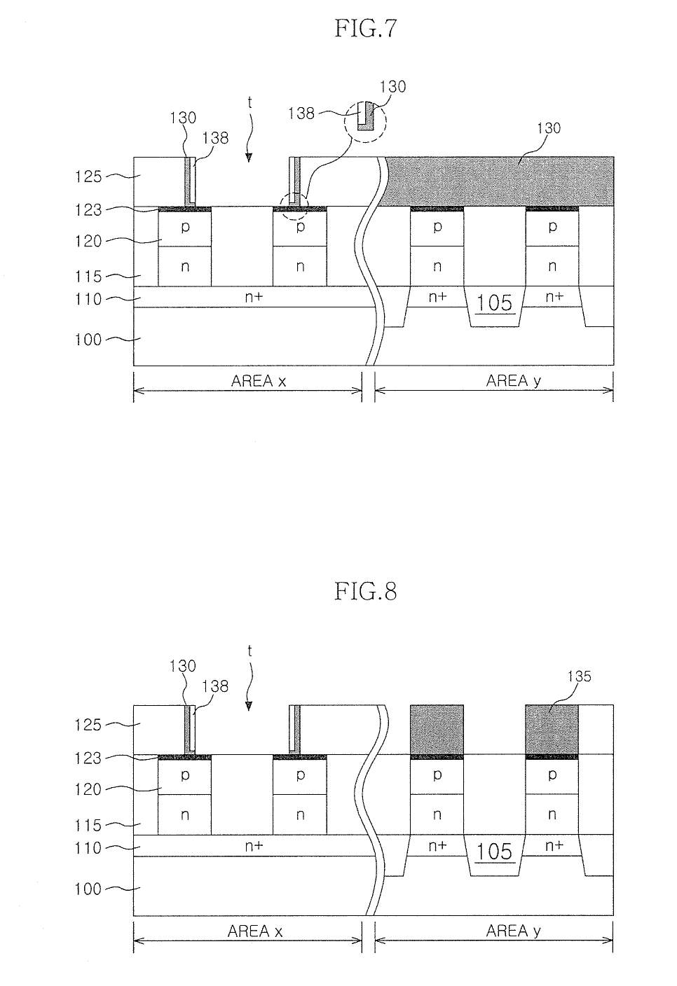

Next, referring to FIGS. 2 and 7, a preliminary heating electrode pattern 130 can be formed on a side wall of the vertical trench t.

The preliminary heating electrode pattern 130 can be formed by sequentially depositing a heating electrode material and a capping layer 138 on the result of the semiconductor substrate 100 where the vertical trench t is formed and subsequently anisotropically etching the capping layer 138 and the heating electrode material on the bottom of the vertical trench t to expose the first interlayer insulating layer 115.

At this time, the heating electrode material configuring the preliminary heating electrode pattern 130 has a comparatively large resistivity. As the heating electrode material, various conductive layers such as a polysilicon layer, a silicon germanium layer (Si—Ge), a titanium nitride layer (TiN), a titanium aluminum nitride layer (TiAlN), etc. can be used and as a possible thin film, a conformally deposited film can be used. Herein, since a deposition thickness of the heating electrode material determines a contact dimension with a phase change structure (not shown) in the embodiment, then the thickness of the heating electrode material should be formed by as thin as possible film. That is, in general, as a contact dimension between the heating electrode and the phase change material in the phase change memory device decreases, a reset current characteristic of the phase change memory device is improved. Therefore, it is important to secure a high reset current characteristic by decreasing the deposition thickness of the heating electrode material. Further, in a present-time semiconductor manufacturing technology, since a thickness can be controlled down to Angstroms (Å), then the contact dimension between the phase change material and the heating electrode can be controlled to a value equal to or less than exposure limits.

Meanwhile, the capping layer 138 is provided to protect the preliminary heating electrode pattern 130 from an etching medium and for substantially preserves an increased contact dimension between the preliminary heating electrode pattern 130 and the switching element 120. That is, while the capping layer 138 is coated, when the capping layer 138 is anisotropically etched, the capping layer 138 remains on the side wall of the preliminary heating electrode pattern 130. As a result, the heating electrode material remains below the capping layer 138, such that a contact surface between the preliminary electrode pattern 130 and the switching element 120 is wider than the top of the preliminary electrode pattern. A silicon nitride film having heat-resistance characteristics can be preferably used as the capping layer 138.

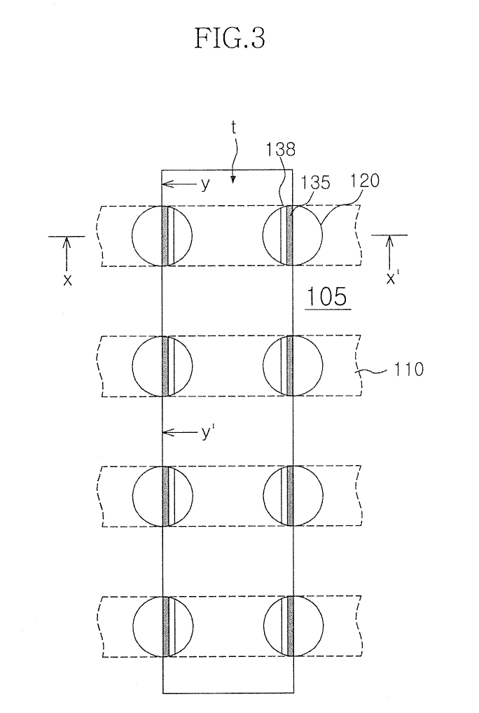

Referring to FIGS. 3 and 8, a heating electrode 135 is formed on the top of each switching element 120.

The heating electrode 135 is formed by node-separating the preliminary heating electrode pattern 130 for each switching element. That is, the heating electrode 135 is formed by patterning the preliminary heating electrode pattern 130 extending on the side wall of the vertical trench t to remain only on the top of the switching element 120. The heating electrode 130 can have a hinge like shape, i.e., an “L” shape, having a horizontal surface and a vertical surface that remains on the capping layer 138 as viewed from the side of the x direction (as viewed in a direction parallel to the active region). Since the heating electrode 135 is formed on the side wall of the vertical trench t, a pair of heating electrodes 135 defined by one vertical trench t are symmetrical to each other to face each other. Further, although not shown in the figure, it will be understood to those skilled in the art that heating electrodes 135 adjacent to each other while being defined by another vertical trench t can also be formed so that vertical surfaces of the hinge shape are substantially symmetrical to each other.

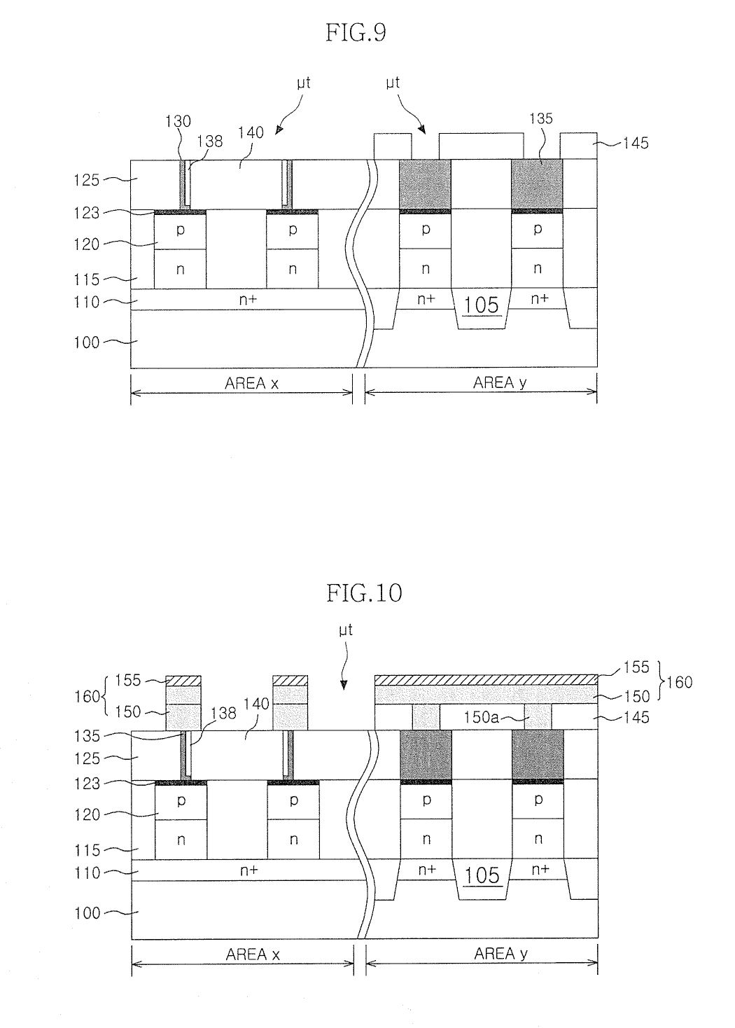

Referring to FIGS. 4 and 9, a fourth interlayer insulating layer 145 including a micro-trench μt that exposes the top of the heating electrode 135 is formed on the top of the planarized result of the semiconductor substrate 100.

More specifically, a third interlayer insulating layer 140 is formed so as to sufficiently fill in a gap between the heating electrodes 135. Next, the third interlayer insulating layer 140 is planarized so as to expose the top of the heating electrode 135. A fourth interlayer insulating layer 145 is deposited on the planarized top of the result of the semiconductor substrate 100. Subsequently, the micro-trench μt is formed by etching the fourth interlayer insulating layer 145 to expose parts of the heating electrodes 135 formed on one active region 110.

The micro-trench μt is configured to define a space where a phase change material will be formed. The micro-trench μt is formed to overlap with the active region 110 while being parallel to the extension direction of the active region 110 and can have a line width smaller than a line width of the heating electrode 135 as viewed in the direction vertical to the extension direction of the active region 110.

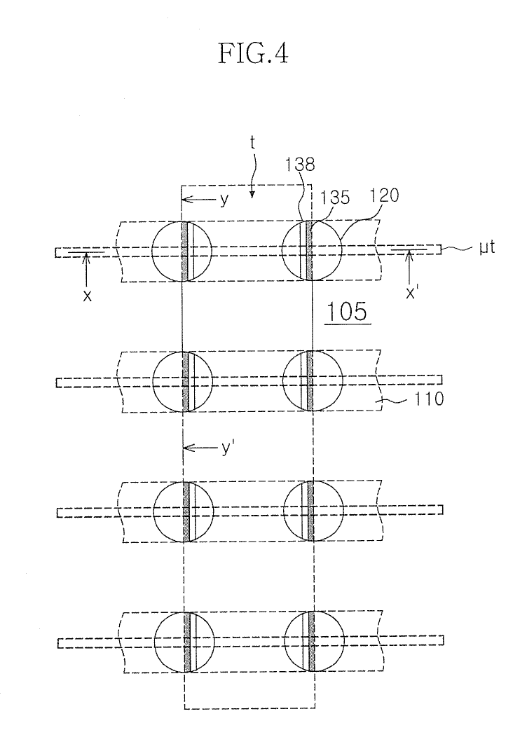

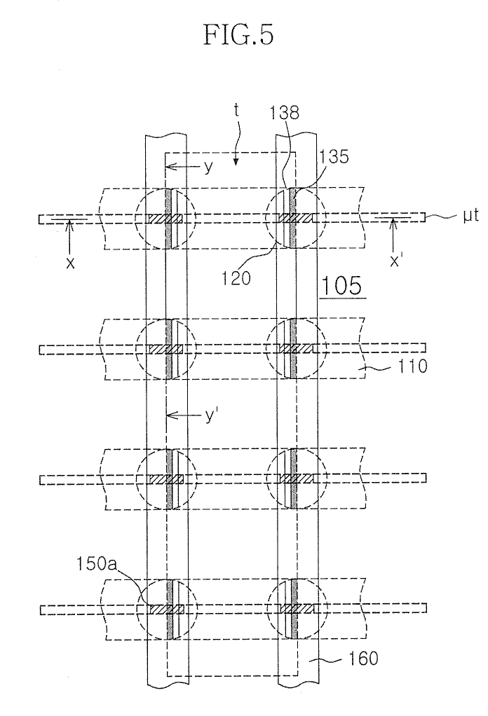

Referring to FIGS. 5 and 10, a phase change structure line 160 having a lower curve that contacts the heating electrode 135 can be formed vertical to the active region 10.

That is, a phase change material layer 150 and an top electrode layer 155 are sequentially laminated on top of the fourth interlayer insulating layer 145 where the micro-trench μt is formed. As the phase change material layer 150, various chalcogenide materials can be used and can be formed thick enough to fill in the micro-trench μt. As the top electrode layer 155, a polysilicon film, a metal nitride film such as a titanium nitride film, or a metal film can be used. The phase change structure line 160 can be formed by patterning the top electrode layer 155 and the phase change material layer 150 vertical to the active region 110.

Therefore, phase change materials buried within the micro-trench μt are partially removed by the patterning, such that the phase change materials are preferably curved on the bottom of the phase change structure line 160, that is, the shape of a cylindrical plug 150a.

Further, while the phase change structure line 160 is spaced from the heating electrode 135 by the thickness of the fourth interlayer insulating layer 145 and the phase change structure line 160 contacts the heating electrode 135 via the plug 150a which projects downwards.

The plug 150a can reduce the contact dimension between the phase change material 150 and the heating electrode 135 and therefore reduce thermal disturbance by extending a thermal transmission path between adjacent phase change materials as viewed in the extension direction of the phase change structure 160 (area y of FIG. 10) along the height of the phase change plug 150a.

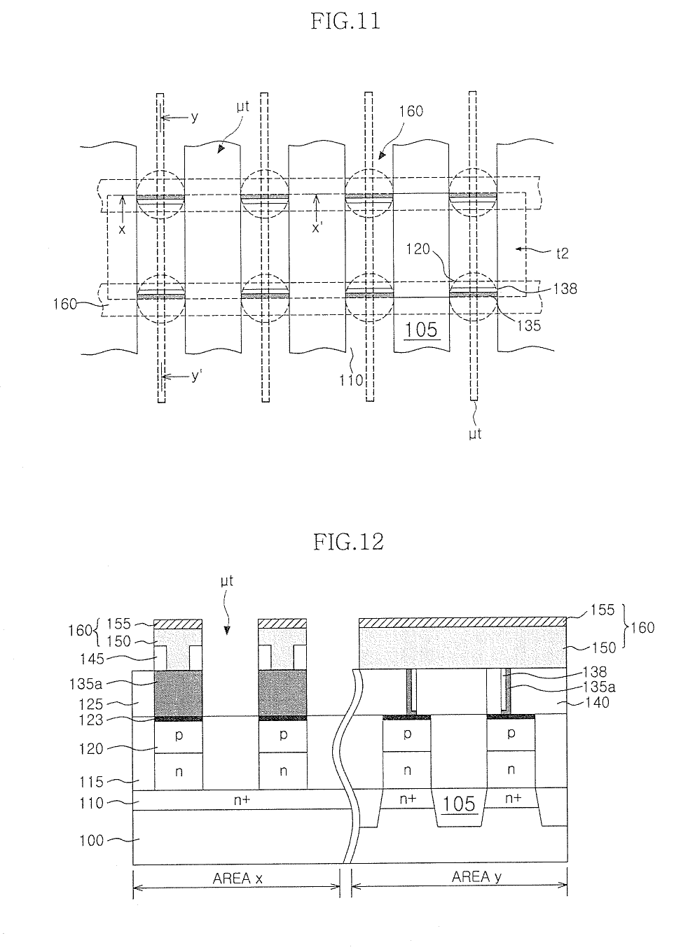

For example, as shown in FIGS. 11 and 12, when a horizontal trench t2 to expose the plurality of switching elements 120 in two rows is formed, the micro-trench μt is formed vertical to the active region 110 and the phase change material 160 is formed vertical to a long axis of the horizontal trench t2.

At this time, the phase change structure 160 and the heating electrode 135a are in direct contact with each other as viewed in the extension direction of the phase change material 160 affecting the disturbance, that is, as viewed from an area y of FIG. 12.

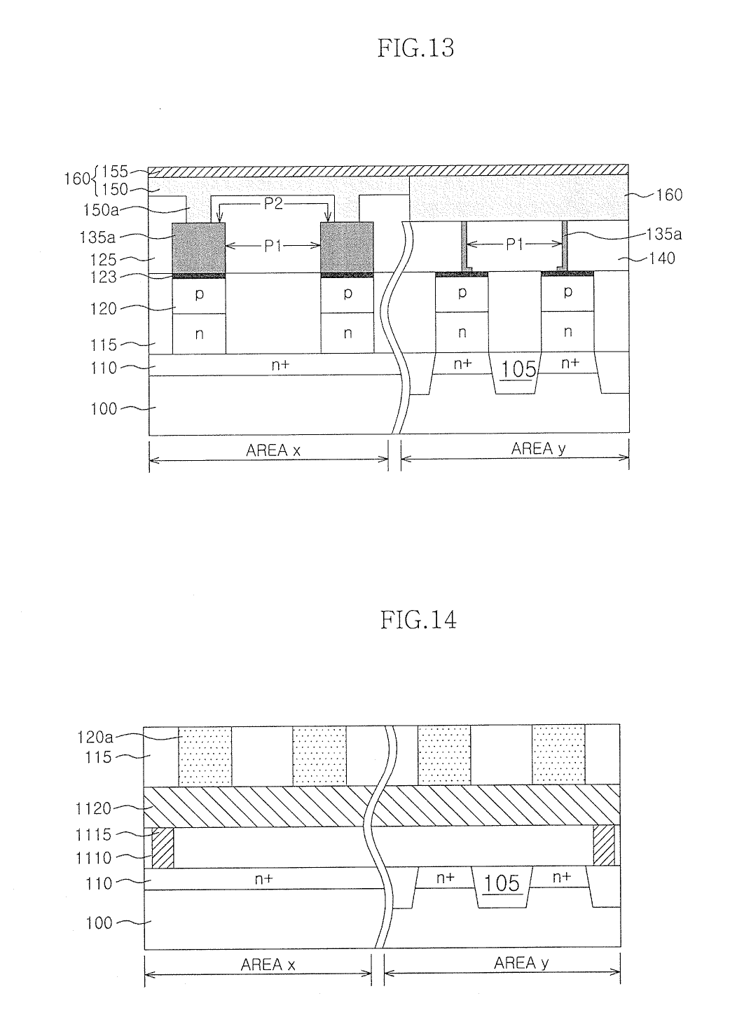

That is, through FIG. 13, when a case in which the vertical trench t is formed (left of the figure) and a case in which the horizontal trench t2 is formed (right of the figure) as viewed in the extension direction of the phase change structure 160 are compared with each other, the bottom of the phase change structure 160 is in direct contact with the phase change structure 160 without a step in case of forming the horizontal trench t2. Therefore, a gap between the adjacent heating electrodes 135a serves as the heat transmission path P1.

Meanwhile, the step is provided on the bottom of the phase change structure 160 by the phase change plug 150a at the time of forming the vertical trench t, such that a heat transmission path P2 between the adjacent heating electrodes 035 has a value acquired by summing up a value corresponding to the gap (i.e., P1) between the heating electrodes 135 and a value corresponding to twice the height of the plug 150a.

As a result, at the time of configuring the phase change memory device by forming the vertical trench t, although planar intervals between the heating electrodes 135 are the same as each other, the heat transmission path extending in the extension direction of the phase change structure line 160 that causes the disturbance can be secured which thereby reduces the problem of disturbance.

Further, in case of using the horizontal trench t2, the phase change structure 160, the fourth interlayer insulating layer 145, and the heating electrode 135a should be etched at the same time as shown in FIG. 12 in order to separate nodes of the heating electrode and the phase change structure 160 from each other. However, since each of the phase change structure 160, the fourth interlayer insulating layer 145, and the heating electrode 135a has a predetermined thickness, a very deep thickness should be etched in order to perform the node separation. As a result, in the case when the layers 160, 145, and 135a are not fully etched, an operation error can occur, and the result of the semiconductor substrate is under severe stress and etching damage due to long-time etching.

In contrast, in case of using the vertical trench t as described in the embodiment, since the heating electrode 135 and the phase change structure 160 can be separately etched, then etching damage can be reduced.

According to the embodiment, the plug 150a projecting downwards is formed at each overlapped portion of the heating electrode on the bottom of the phase change structure line 160. Therefore, since the heat transmission path between the phase change structure line 160 and the heating electrode 135 can be substantially extended by more than a length twice the height of the plug 150a in the extension direction of the phase change structure line 160, it is then possible to remarkably improve the thermal disturbance of a high-integrated phase change memory device.

While certain embodiments have been described above, it will be understood that the embodiments described are by way of example only. Accordingly, the device and method described herein should not be limited based on the described embodiments. Rather, the devices and methods described herein should only be limited in light of the claims that follow when taken in conjunction with the above description and accompanying drawings.

What is claimed is:

1. A phase change memory device, comprising:
a semiconductor substrate;
a plurality of active regions on the semiconductor substrate, the active regions being substantially linear and parallel to each other;
a plurality of phase change structure lines formed on the top of the semiconductor substrate and disposed substantially in parallel to each other, the phase change structure lines being disposed substantially vertical to a linear direction of the active regions;
a plurality of heating electrode at intersections of the active regions and the phase change structure lines and coupled to the phase change structure lines, wherein the phase change structure lines are spaced away from the heating electrodes; and
a plurality of plugs coupling together the heating electrodes to a bottom of the phase change structure lines at the intersections.

2. The phase change memory device of claim 1, further comprising a plurality of switching elements coupling together the active regions to the heating electrodes.

3. The phase change memory device of claim 2, further comprising a plurality of metal word line in parallel to the active regions, the metal word lines coupling together the active regions and the switching elements.

4. The phase change memory device of claim 2, wherein a contact area between the heating electrodes and the switching elements is larger than a connect area between the heating electrodes and the phase change structure line.

5. The phase change memory device of claim 4, wherein the heating electrodes have “L” shapes that have horizontal surfaces coupled to the switching elements and vertical surfaces coupled to the phase change structure lines.

6. The phase change memory device of claim 5, further comprising a plurality of capping layers connected to the horizontal surfaces and the vertical surfaces of the heating electrodes.

7. The phase change memory device of claim 5, wherein the capping layers substantially preserve an increased contact area between the heating electrodes and the switching elements by protecting the heating electrodes from being etched by a etching medium.

8. The phase change memory device of claim 1, wherein the phase change structure lines include:
a phase change material; and
top electrodes coupled to the phase change material.

9. The phase change memory device of claim 8, wherein the plugs are made of the phase change material.

10. The phase change memory device of claim 1, wherein the plugs defining an electrical pathway between the heating electrodes and the phase change structure lines which is determined by a cross sectional area of the plug.

11. A phase change memory device, comprising:
a plurality of active regions being linear and parallel to each other;
a plurality of switching elements coupled to the active regions;
a plurality of heating electrodes on and coupled to the switching elements; and
a plurality of phase change structure lines coupled to the heating electrodes, the phase change structure lines substantially vertical to the active regions,
wherein the phase change structure lines includes a plurality of plugs projecting downwards that couple to overlapped portions of the heating electrodes.

12. The phase change memory device of claim 11, further comprising a plurality of metal word lines that extend parallel to the active regions, the metal word lines coupling together the active regions and the switching elements.

13. The phase change memory device of claim 11, wherein a contact area between the heating electrodes and the switching elements is larger than a connect area between the heating electrodes and the phase change structure lines.

14. The phase change memory device of claim 13, wherein the heating electrodes have “L” shapes that have horizontal surfaces coupled to the switching elements and vertical surfaces coupled to the phase change structure lines.

15. The phase change memory device of claim 14, further comprising a plurality of capping layers connected to horizontal surfaces and vertical surfaces of the heating electrodes.

16. The phase change memory device of claim 15, wherein the capping layers comprise silicon nitride.

17. The phase change memory device of claim 15, wherein the capping layers substantially preserve an increased contact area between the heating electrodes and the switching elements by protecting the heating electrodes from being etched by an etching medium.

18. The phase change memory device of claim 11, wherein the phase change structure lines includes:
a phase change material; and
top electrodes on top and coupled to the phase change material.

19. The phase change memory device of claim 18, wherein the plug comprises the phase change material.

20. The phase change memory device of claim 19, wherein the plugs defining an electrical pathway between the heating electrodes and the phase change structure lines which is determined by a cross sectional area of the plug.

21. A method of manufacturing a phase change memory device, comprising:
forming a plurality of active regions on a semiconductor substrate such that the active regions are substantially linear and parallel to each other;
forming a first interlayer insulating layer including forming a plurality of switching elements coupled to the active region, the first interlayer insulating layer formed on top of the semiconductor substrate and the switching elements formed on top of the semiconductor substrate where the active region is formed;
forming a second interlayer insulating layer having a vertical trench that exposes two columns of switching elements in the first interlayer insulating layer;
forming a preliminary heating electrode pattern on a side wall of the vertical trench;
forming heating electrodes on the switching elements by separating the preliminary heating electrode pattern;
burying a third interlayer insulating layer within gaps between the heating electrodes;
forming a fourth interlayer insulating layer including micro-trenches which extends parallel to the active regions and which expose the heating electrodes along the second and third interlayer insulating layers; and
forming phase change structure lines that extend substantially vertical to a linear direction of the active regions such that the phase change structure lines couple to the heating electrodes exposed by the micro-trenches.

22. The method of manufacturing a phase change memory device of claim 21, further comprising forming a metal word line coupled to the active region and forming the first interlayer insulating layer.

23. The method of manufacturing a phase change memory device of claim 21, wherein forming a preliminary heating electrode pattern includes:
depositing a heating electrode material on the second interlayer insulating layer having the vertical trench;
depositing a heating capping layer on the heating electrode material; and
anisotropically etching the heating capping layer and the heating electrode material.

24. The method of manufacturing a phase change memory device of claim 21, wherein the micro-trenches are thinner than the heating electrodes.

25. The method of manufacturing a phase change memory device of claim 21, wherein forming a phase change structure line includes:
depositing the phase change material on the fourth interlayer insulating layer to fill in the micro-trenches;
depositing a top electrode material onto the phase change material; and
patterning the upper electrode material and the phase change material to overlap with the heating electrodes to form upper electrodes that are vertical to the linear direction of the active region.
